(19) United States
(12) Patent Application Publication
(10) Pub. No.: US 2026/0053059 A1
(43) Pub. Date: Feb. 19, 2026

(54) PACKAGE STRUCTURE INCLUDING AT LEAST TWO MEMORY DEVICES, ASSEMBLY STRUCTURE AND METHOD OF MANUFACTURING THE SAME

(71) Applicant: NANYA TECHNOLOGY CORPORATION, NEW TAIPEI CITY (TW)

(72) Inventors: SHING-YIH SHIH, NEW TAIPEI CITY (TW); TSE-YAO HUANG, NEW TAIPEI CITY (TW)

(21) Appl. No.: 18/804,435

(22) Filed: Aug. 14, 2024

(51) Int. Cl. H01L 25/18; H01L 23/00; H01L 23/31; H01L 23/48; H10B 80/00

(52) U.S. Cl. CPC H01L 25/18; H01L 23/481; H01L 24/08; H01L 24/16; H01L 23/3107; H01L 2224/08146; H01L 2224/16146; H10B 80/00

(57) ABSTRACT

A package structure, an assembly structure and a manufacturing method are provided. The package structure includes a molded structure, a logic device, a non-volatile memory device and a volatile memory device. The molded structure includes a memory controller device, an interconnection device and an encapsulant encapsulating the memory controller device and the interconnection device. The logic device is electrically connected to the interconnection device. The non-volatile memory device and the volatile memory device are electrically to the logic device through the memory controller device. The volatile memory device is electrically connected to the non-volatile memory device through the memory controller device.

### TECHNICAL FIELD

The present disclosure relates to a package structure, an assembly structure and a method of manufacturing the same, and more particularly, to a package structure including at least two memory devices, an assembly structure including the package structure, and a method of manufacturing the same.

### DISCUSSION OF THE BACKGROUND

Semiconductor electronic products are widely used in various electronic applications, and their dimensions are constantly being reduced to meet the demands of current applications. However, scaling down semiconductor electronic products presents several challenges that affect their final electrical characteristics, quality, cost, and yield. As semiconductor electronic products become smaller, they require multifunctional and high-volume data processing capabilities. Consequently, there is an increasing need to enhance the integration level of semiconductor devices used in these electronic products. However, due to the limitations of semiconductor integration technology, it is challenging to meet all the required functions with just a single semiconductor chip. To address this issue, semiconductor packages have been developed, which involve including multiple semiconductor chips.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a package structure including a molded structure, a logic device, a non-volatile memory device and a volatile memory device. The molded structure includes a memory controller device, an interconnection device and an encapsulant. The memory controller device includes a conductive structure including a first circuit, a second circuit and a third circuit. The interconnection device is disposed side by side with the memory controller device, and includes a conductive structure. The encapsulant encapsulates the memory controller device and the interconnection device. The logic device is disposed over the molded structure, and includes a conductive structure including a fourth circuit, a fifth circuit and a sixth circuit. The sixth circuit of the logic device is electrically connected to the conductive structure of the interconnection device. The non-volatile memory device is disposed over the molded structure, and electrically connected to the fourth circuit of the logic device through the second circuit of the memory controller device. The volatile memory device is disposed over the molded structure, and electrically connected to the fifth circuit of the logic device through the third circuit of the memory controller device. The volatile memory device is electrically connected to the non-volatile memory device through the first circuit of the memory controller device.

Another aspect of the present disclosure provides an assembly structure including a substrate, an interconnection device, a first memory controller device, a second memory controller device, a logic device, a first non-volatile memory device, a first volatile memory device, a second non-volatile memory device and a second volatile memory device. The interconnection device is disposed over and electrically connected to the substrate. The first memory controller device is disposed over and electrically connected to the substrate. The second memory controller device is disposed over and electrically connected to the substrate, wherein the first memory controller device and the second memory controller device are disposed at different sides of the interconnection device. The logic device is disposed over and electrically connected to the interconnection device, the first memory controller device and the second memory controller device. The first non-volatile memory device is disposed over and electrically connected to the first memory controller device. The first volatile memory device is disposed side by side with the first non-volatile memory device, and disposed over and electrically connected to the first memory controller device. The second non-volatile memory device is disposed over and electrically connected to the second memory controller device. The second volatile memory device is disposed side by side with the second non-volatile memory device, and disposed over and electrically connected to the second memory controller device.

Another aspect of the present disclosure provides a manufacturing method. The manufacturing method includes: providing a molded structure, wherein the molded structure includes a first memory controller device, an interconnection device disposed side by side with the first memory controller device, and an encapsulant encapsulating the first memory controller device and the interconnection device; electrically connecting a logic device to the first memory controller device and the interconnection device; and electrically connecting a first volatile memory device and a first non-volatile memory device to the first memory controller device.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 illustrates, in a flowchart diagram form, a method for manufacturing an assembly structure in accordance with one embodiment of the present disclosure.

FIGS. 2A to 12C illustrate stages of a method for manufacturing the assembly structure in accordance with one embodiment of the present disclosure.

FIG. 13 illustrates a schematic cross-sectional view of an assembly structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

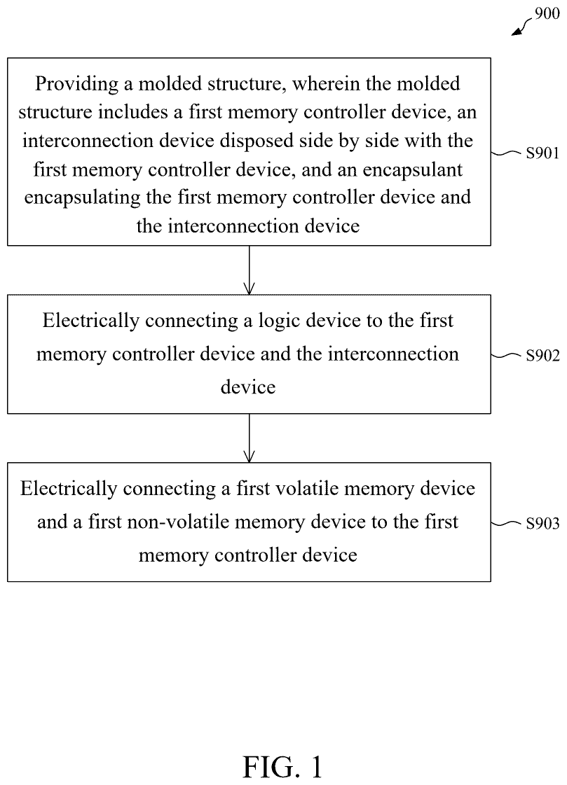

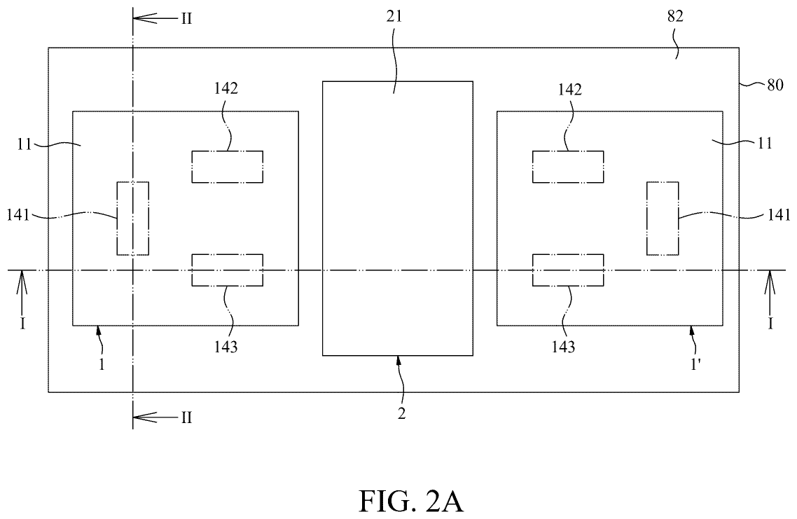

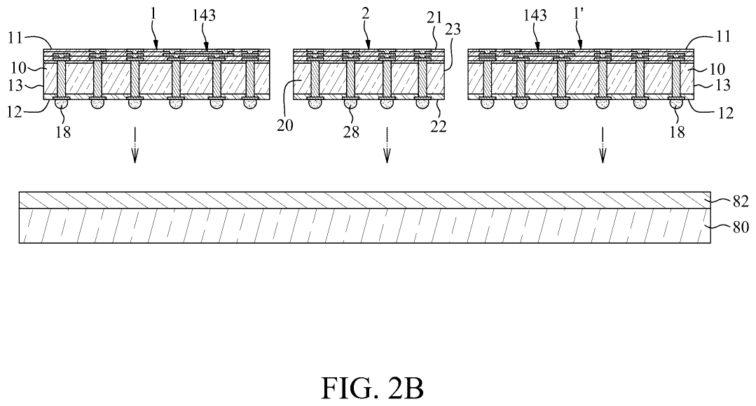

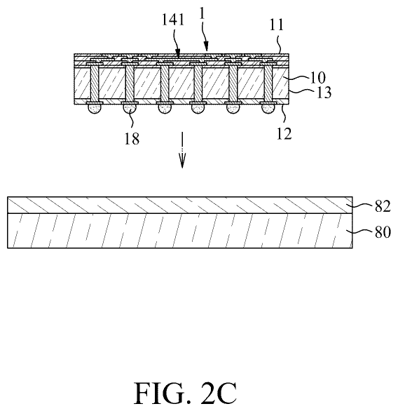

FIG. 1 illustrates, in a flowchart diagram form, a method 900 for manufacturing an assembly structure 7 in accordance with one embodiment of the present disclosure. FIGS. 2A to 12C illustrate stages of a method for manufacturing the assembly structure 7 in accordance with one embodiment of the present disclosure. In some embodiments, FIGS. 2A to 11D illustrate stages of a method for manufacturing a package structure 6 in accordance with one embodiment of the present disclosure. At least some of these figures have been simplified for a better understanding of the aspects of the present disclosure.

With reference to FIGS. 2A to 6B, at step S901, a molded structure 8 may be provided or formed.

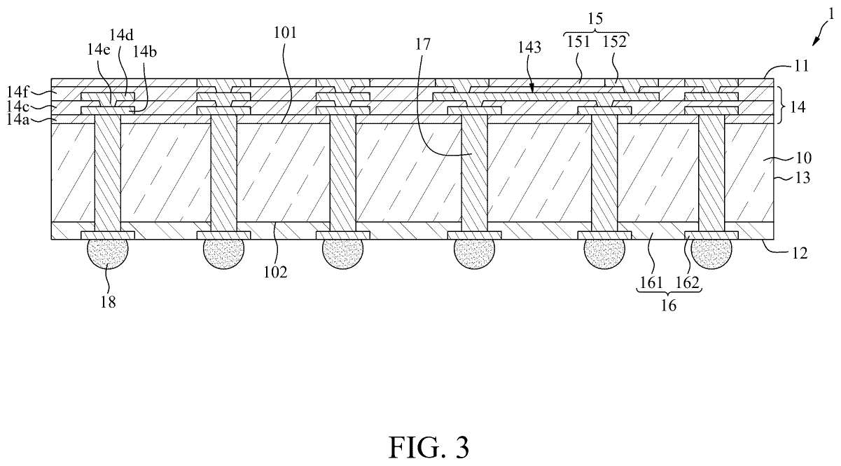

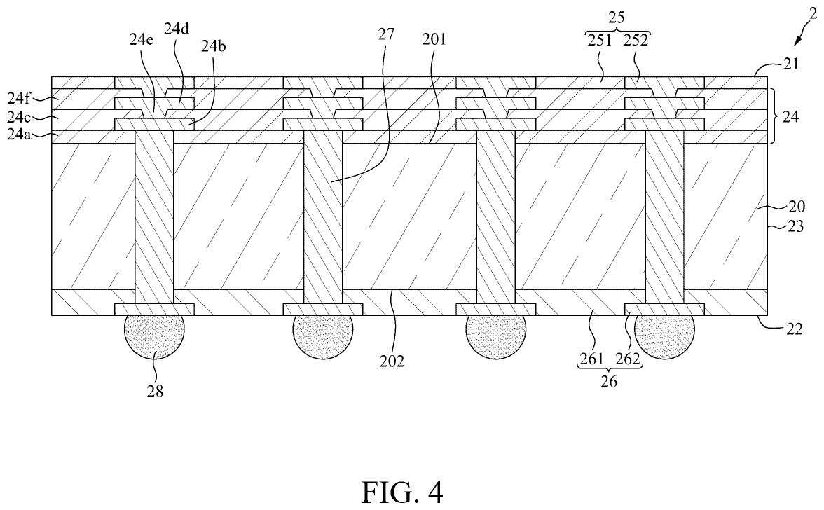

With reference to FIGS. 2A, 2B, 2C, 3, and 4, a first memory controller device 1, an interconnection device 2, a second memory controller device 1′ and a carrier 80 with an adhesive layer 82 (or a release layer) may be provided. FIG. 2A may illustrate a top view of FIGS. 2B and 2C. Alternatively, FIG. 2B may illustrate a cross-sectional view of FIG. 2A taken along line I-I. FIG. 2C may illustrate a cross-sectional view of FIG. 2A taken along line II-II. FIG. 3 may illustrate a schematic cross-sectional view of the first memory controller device 1 in accordance with some embodiments of the present disclosure. FIG. 4 may illustrate a schematic cross-sectional view of the interconnection device 2 in accordance with some embodiments of the present disclosure.

The function and size of the first memory controller device 1 may be different from the function and size of the interconnection device 2. The function and size of the first memory controller device 1 may be same as the function and size of the second memory controller device 1′. A thickness of the first memory controller device 1 may be equal to a thickness of the interconnection device 2 and a thickness of the second memory controller device 1′.

In some embodiments, the first memory controller device 1 may be configured to control different memory devices, and may be also referred to as “first memory controller die”, “first memory controller chip”, “first memory controller semiconductor die”, or “first memory controller semiconductor chip”. The interconnection device 2 may be configured for vertical electrical connection, and may be also referred to as “interconnection die”, “interconnection chip”, “interconnection semiconductor die”, “interconnection semiconductor chip”, “interposer”, “interposer die”, or “interposer chip”. The second memory controller device 1′ may be configured to control different memory devices, and may be also referred to as “second memory controller die”, “second memory controller chip”, “second memory controller semiconductor die”, or “second memory controller semiconductor chip”.

Referring to FIG. 3, the first memory controller device 1 may have a top surface 11 (e.g., a first surface), a bottom surface 12 (e.g., a second surface) and a lateral surface 13 extending between the top surface 11 and the bottom surface 12. The first memory controller device 1 may include a first base portion 10, a first conductive structure 14, a first upper structure 15, a first lower structure 16, a plurality of first conductive vias 17 and a plurality of solder materials 18.

The first base portion 10 may have a first surface 101 (e.g., a top surface) and a second surface 102 (e.g., a bottom surface) opposite to the first surface 101. The first base portion 10 may be a semiconductor substrate, and may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials, or combinations thereof. In some embodiments, the first base portion 10 may include a semiconductor-on-insulator substrate, such as a silicon-on-insulator (SOI) substrate, a silicon germanium-on-insulator (SGOI) substrate, or a germanium-on-insulator (GOI) substrate. In some embodiments, the first base portion 10 may be a bulk semiconductor substrate that is composed entirely of at least one semiconductor material; the bulk semiconductor substrate does not contain any dielectrics, insulating layers, or conductive features.

The first conductive structure 14 may be formed or disposed on the first surface 101 (e.g., the top surface) of the first base portion 10. In some embodiments, the first conductive structure 14 may include a plurality of front-end-of-line (FEOL) devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof. In some embodiments, the first conductive structure 14 may further include at least one back-end-of-line (BEOL) interconnect pattern, e.g., a plurality of patterned circuit layers, electrically connected to the front-end-of-line (FEOL) devices. In some embodiments, the first conductive structure 14 may further include at least one dielectric layer or at least one dielectric structure covering the front-end-of-line (FEOL) devices and the back-end-of-line (BEOL) interconnect pattern.

The first conductive structure 14 may include a first dielectric layer 14a, a first circuit layer 14b (including a plurality traces and a plurality of pads), a second dielectric layer 14c, a second circuit layer 14d (including a plurality trace and a plurality of pads), a plurality of inner vias 14e and a third dielectric layer 14f. The first dielectric layer 14a may be disposed on the first surface 101 (e.g., a top surface) of the first base portion 10. The first dielectric layer 14a may be an interlayer dielectric (ILD) layer, and may include SiO2, SiN, and/or SiCN. The first circuit layer 14b (including the traces and the pads) may be disposed on the first dielectric layer 14a.

The second dielectric layer 14c may be disposed on the first dielectric layer 14a to cover the first circuit layer 14b. The second dielectric layer 14c may be an inter-metal dielectric (IMD) layer, and may include SiO2, SiN, and/or SiCN. The second circuit layer 14d (including the traces and the pads) may be disposed on the second dielectric layer 14c.

The inner vias 14e may be disposed in the second dielectric layer 14c, and may connect the first circuit layer 14b and the second circuit layer 14d. The third dielectric layer 14f may surround the second circuit layer 14d. The third dielectric layer 14f may include SiO2, SiN, and/or SiCN.

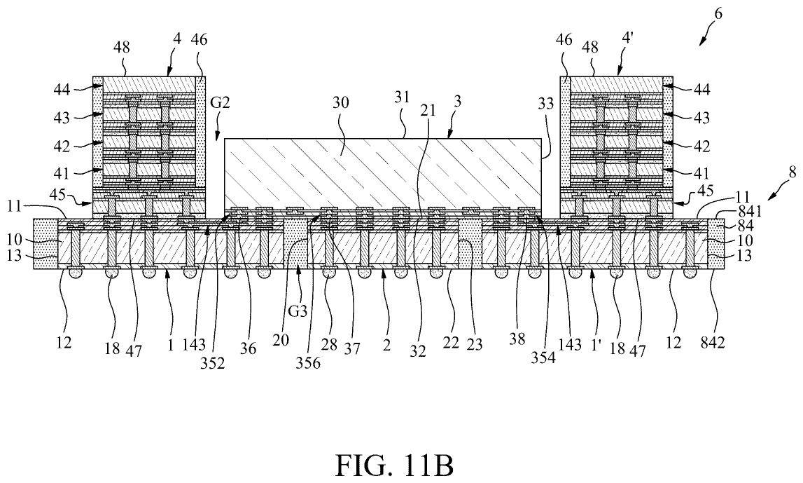

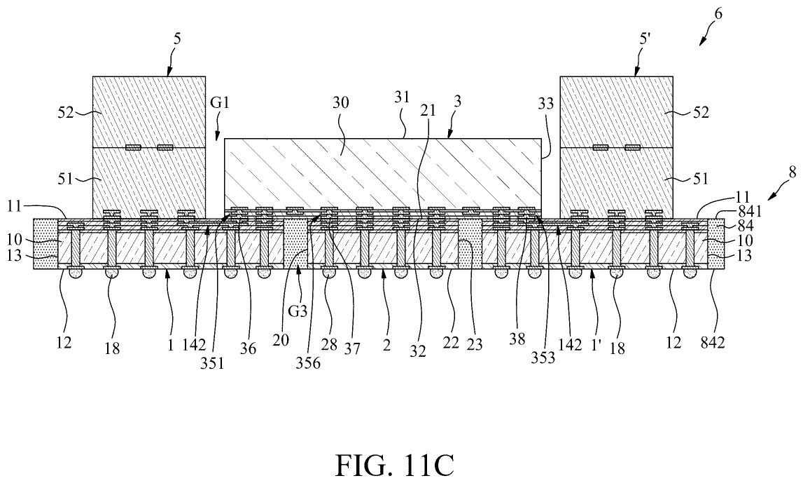

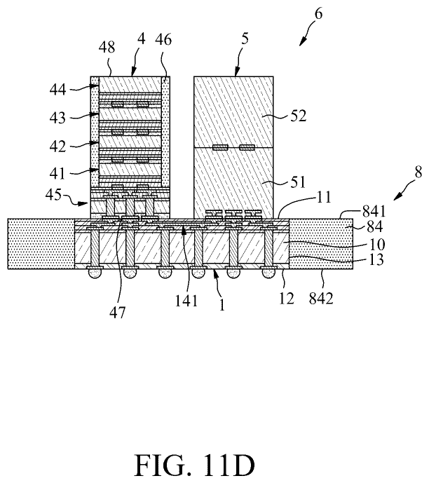

Referring to FIG. 2A, the second circuit layer 14d of the first conductive structure 14 may include a first circuit 141 (FIG. 11D), a second circuit 142 (FIG. 11C) and a third circuit 143 (FIG. 2B). The first circuit 141 may be also referred to as “first circuit region”, “first circuit structure”, or “first circuit trace”. The second circuit 142 may be also referred to as “second circuit region”, “second circuit structure”, or “second circuit trace”. The third circuit 143 may be also referred to as “third circuit region”, “third circuit structure”, or “third circuit trace”. The first circuit 141, the second circuit 142 and the third circuit 143 of the first memory controller device 1 may be spaced apart from each other, and may not electrically connected to each other in a horizontal direction. The horizontal direction may be defined as a direction substantially parallel with the top surface 21 of the interconnection device 2 or the top surface 11 of the first memory controller device 1.

Referring to FIG. 3, the first upper structure 15 may be formed or disposed on the first conductive structure 14. The first upper structure 15 may include a first upper dielectric layer 151 and a plurality of first upper pads 152. The first upper pads 152 may be disposed on the second circuit layer 14d, and may be embedded in the first upper dielectric layer 151. Each of the first upper pads 152 may be a hybrid bonding (HB) pad and may include Cu or Al. Each of the first upper pads 152 may be a solder bonding pad. The first upper pads 152 may be exposed by the first upper dielectric layer 151. The first upper dielectric layer 151 may be a hybrid bonding (HB) dielectric layer, and may include SiO2, SiN, and/or SiCN. In some embodiments, a top surface of the first upper pad 152 may be substantially aligned with a top surface of the first upper dielectric layer 151. In some embodiments, a thickness of the first upper pad 152 may be substantially equal to a thickness of the first upper dielectric layer 151.

The first conductive vias 17 may be formed or disposed in the first base portion 10, and may extend beyond the first surface 101 (e.g., the top surface) of the first base portion 10. The first conductive vias 17 may extend through the first dielectric layer 14a to connect or contact the first circuit layer 14b. Thus, the first conductive vias 17 may extend into the first conductive structure 14, and may be electrically connected to the first conductive structure 14. Thus, the first upper pads 152 may be electrically connected to the first conductive vias 17 through the first conductive structure 14. In addition, the first conductive vias 17 may extend beyond the second surface 102 (e.g., the bottom surface) of the first base portion 10. The first conductive vias 17 may extend through the first base portion 10. Thus, the first conductive via 17 may be a monolithic structure, and a length of the first conductive via 17 may be greater than a thickness of the first base portion 10.

The first lower structure 16 may be formed or disposed on the second surface 102 (e.g., the bottom surface) of the first base portion 10. The first lower structure 16 may include a first lower dielectric layer 161 and a plurality of first lower pads 162. The first lower dielectric layer 161 may be disposed on the second surface 102 (e.g., the bottom surface) of the first base portion 10, and may cover a bottom portion of the first conductive via 17. The first lower dielectric layer 161 may be a hybrid bonding (HB) dielectric layer, and may include SiO2, SiN, and/or SiCN.

The first lower pads 162 may be embedded in the first lower dielectric layer 161, and may be exposed by the first lower dielectric layer 161. The first lower pads 162 may be electrically connected to the first conductive vias 17. In some embodiments, the first lower pads 162 may directly contact the first conductive vias 17. Each of the first lower pads 162 may be a hybrid bonding (HB) pad, and may include Cu or Al. Each of the first lower pads 162 may be a solder bonding pad. In some embodiments, a bottom surface of the first lower pad 162 may be substantially aligned with a bottom surface of the first lower dielectric layer 161. In some embodiments, a thickness of the first lower pad 162 may be less than a thickness of the first lower dielectric layer 161.

The solder materials 18 may be reflowable solder materials, and may be disposed on the first lower pads 162.

Referring to FIG. 4, a structure of the interconnection device 2 may be similar to the structure of the first memory controller device 1. The interconnection device 2 may have a top surface 21 (e.g., a first surface), a bottom surface 22 (e.g., a second surface) and a lateral surface 23 extending between the top surface 21 and the bottom surface 22. The interconnection device 2 may include a base portion 20, a conductive structure 24, an upper structure 25, a lower structure 26, a plurality of conductive vias 27 and a plurality of solder materials 28.

The base portion 20 may have a first surface 201 (e.g., a top surface) and a second surface 202 (e.g., a bottom surface) opposite to the first surface 201. The base portion 20 may be similar to the first base portion 10 of the first memory controller device 1.

The conductive structure 24 may be formed or disposed on the first surface 201 (e.g., the top surface) of the base portion 20. In some embodiments, the conductive structure 24 may be similar to the first conductive structure 14 of the first memory controller device 1. The conductive structure 24 may include a first dielectric layer 24a, a first circuit layer 24b (including a plurality traces and a plurality of pads), a second dielectric layer 24c, a second circuit layer 24d (including a plurality trace and a plurality of pads), a plurality of inner vias 24e and a third dielectric layer 24f. The first dielectric layer 24a may be disposed on the first surface 201 (e.g., a top surface) of the base portion 20. The first circuit layer 24b may be disposed on the first dielectric layer 24a.

The second dielectric layer 24c may be disposed on the first dielectric layer 24a to cover the first circuit layer 24b. The second circuit layer 24d may be disposed on the second dielectric layer 24c. The inner vias 24e may be disposed in the second dielectric layer 24c, and may connect the first circuit layer 24b and the second circuit layer 24d. The third dielectric layer 24f may surround the second circuit layer 24d.

The upper structure 25 may be formed or disposed on the conductive structure 24. The upper structure 25 may include an upper dielectric layer 251 and a plurality of upper pads 252. The upper pads 252 may be disposed on the second circuit layer 24d, and may be embedded in the upper dielectric layer 251. Each of the upper pads 252 may be a hybrid bonding (HB) pad. The upper pads 252 may be exposed by the upper dielectric layer 251. The upper dielectric layer 251 may be a hybrid bonding (HB) dielectric layer. In some embodiments, a top surface of the upper pad 252 may be substantially aligned with a top surface of the upper dielectric layer 251. In some embodiments, a thickness of the upper pad 252 may be substantially equal to a thickness of the upper dielectric layer 251.

The conductive vias 27 may be formed or disposed in the base portion 20, and may extend beyond the first surface 201 (e.g., the top surface) of the base portion 20. The conductive vias 27 may extend through the first dielectric layer 24a to connect or contact the first circuit layer 24b. Thus, the conductive vias 27 may extend into the conductive structure 24, and may be electrically connected to the conductive structure 24. Thus, the upper pads 252 may be electrically connected to the conductive vias 27 through the conductive structure 24. In addition, the conductive vias 27 may extend beyond the second surface 202 (e.g., the bottom surface) of the base portion 20. The conductive vias 27 may extend through the base portion 20.

The lower structure 26 may be formed or disposed on the second surface 202 (e.g., the bottom surface) of the base portion 20. The lower structure 26 may include a lower dielectric layer 261 and a plurality of lower pads 262. The lower dielectric layer 261 may be disposed on the second surface 202 (e.g., the bottom surface) of the base portion 20, and may cover a bottom portion of the conductive via 27. The lower dielectric layer 261 may be a hybrid bonding (HB) dielectric layer.

The lower pads 262 may be embedded in the lower dielectric layer 261, and may be exposed by the lower dielectric layer 261. The lower pads 262 may be electrically connected to the conductive vias 27. In some embodiments, the lower pads 262 may directly contact the conductive vias 27. Each of the lower pads 262 may be a hybrid bonding (HB) pad. In some embodiments, a bottom surface of the lower pad 262 may be substantially aligned with a bottom surface of the lower dielectric layer 261. In some embodiments, a thickness of the lower pad 262 may be less than a thickness of the lower dielectric layer 261.

The solder materials 28 may be reflowable solder materials, and may be disposed on the lower pads 262.

Referring to FIG. 2B, a structure of the second memory controller device 1′ may be same as or similar to the structure of the first memory controller device 1. The second memory controller device 1′ may have a top surface 11 (e.g., a first surface), a bottom surface 12 (e.g., a second surface) and a lateral surface 13 extending between the top surface 11 and the bottom surface 12. The first memory controller device 1 may include a first circuit 141, a second circuit 142, a third circuit 143 and a plurality of solder materials 18.

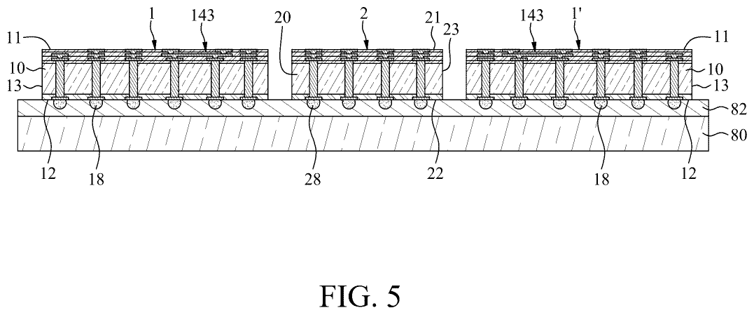

With reference to FIG. 5, the first memory controller device 1, the interconnection device 2 and the second memory controller device 1′ may be attached to or adhered to the adhesive layer 82 (or the release layer) of the carrier 80. The first memory controller device 1, the interconnection device 2 and the second memory controller device 1′ may be arranged in a row. The interconnection device 2 may be disposed side by side with the first memory controller device 1 and the second memory controller device 1′. The first memory controller device 1 and the second memory controller device 1′ may be disposed at different sides of the interconnection device 2.

The solder materials 18 of the first memory controller device 1 may be embedded in the adhesive layer 82 (or the release layer), and the bottom surface 12 of the first memory controller device 1 may contact a top surface of the adhesive layer 82 (or the release layer). In addition, the solder materials 28 of the interconnection device 2 may be embedded in the adhesive layer 82 (or the release layer), and the bottom surface 22 of the interconnection device 2 may contact the top surface of the adhesive layer 82 (or the release layer). Similarly, the solder materials 18 of the second memory controller device 1′ may be embedded in the adhesive layer 82 (or the release layer), and the bottom surface 12 of the second memory controller device 1′ may contact the top surface of the adhesive layer 82 (or the release layer).

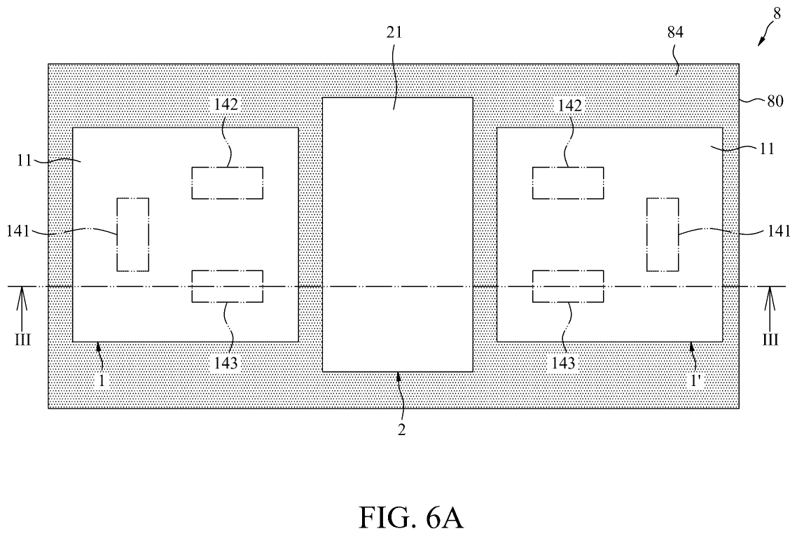

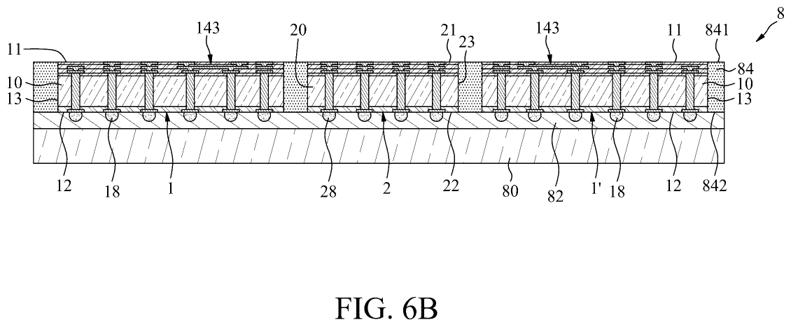

With reference to FIGS. 6A and 6B, an encapsulant 84 may be formed or disposed on the adhesive layer 82 (or the release layer) of the carrier 80 to encapsulate the first memory controller device 1, the interconnection device 2 and the second memory controller device 1′. FIG. 6A may illustrate a top view of FIG. 6B. Alternatively, FIG. 6B may illustrate a cross-sectional view of FIG. 6A taken along line III-III.

The encapsulant 84 may be a molding compound with or without fillers. The encapsulant 84 may have a top surface 841 and a bottom surface 842 opposite to the top surface 841. The top surface 11 and the bottom surface 12 of the first memory controller device 1 are substantially aligned with the top surface 841 and the bottom surface 842 of the encapsulant 84, respectively. The top surface 21 and the bottom surface 22 of the interconnection device 2 are substantially aligned with the top surface 841 and the bottom surface 842 of the encapsulant 84, respectively. The top surface and the bottom surface of the second memory controller device 1′ are substantially aligned with the top surface 841 and the bottom surface 842 of the encapsulant 84, respectively.

Meanwhile, the molded structure 8 may be provided or formed. The molded structure 8 may include the first memory controller device 1, the second memory controller device 1′, the interconnection device 2 and the encapsulant 84. The first memory controller device 1, the second memory controller device 1′ and the interconnection device 2 are disposed side by side. The encapsulant 84 encapsulates the first memory controller device 1, the second memory controller device 1′ and the interconnection device 2.

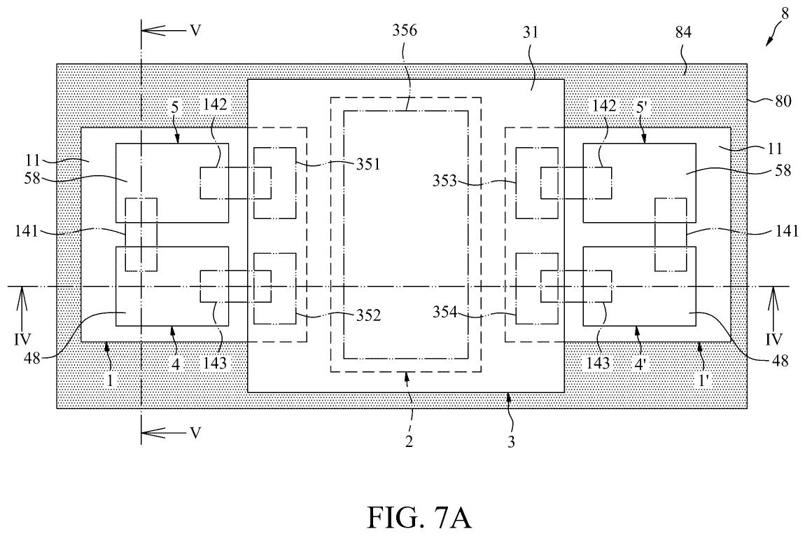

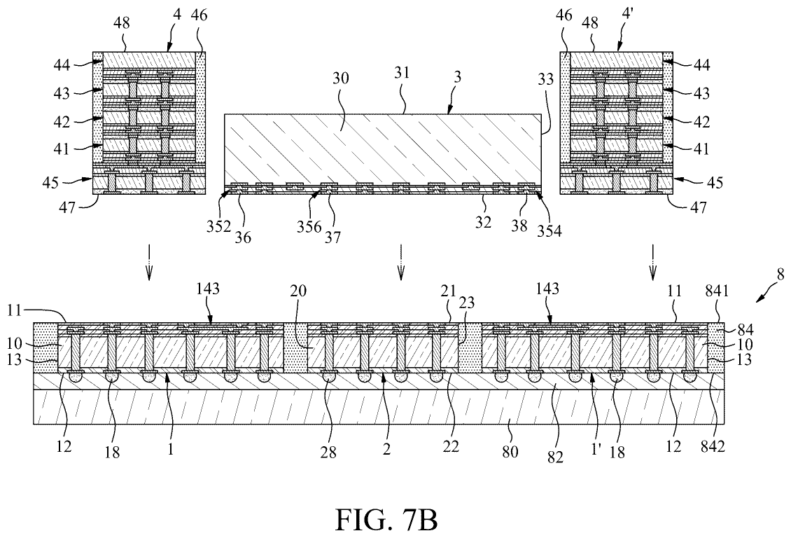

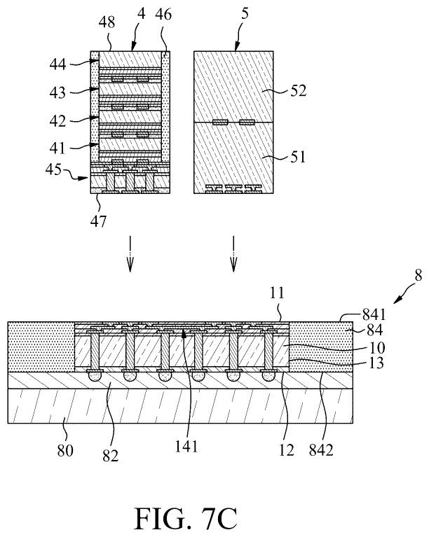

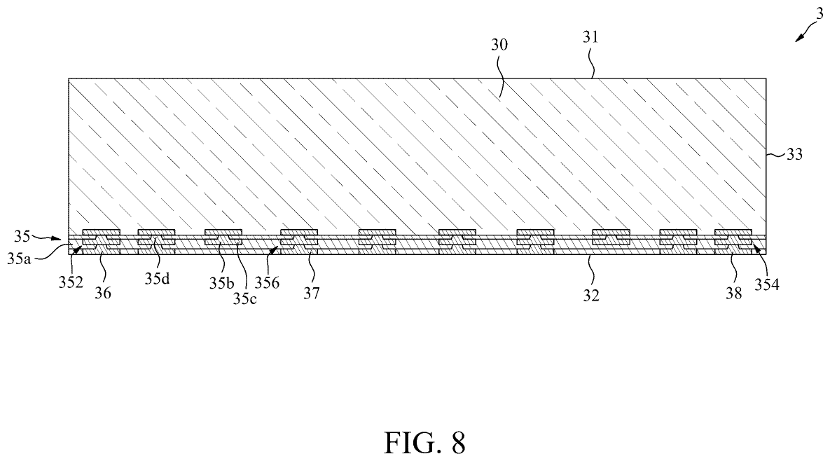

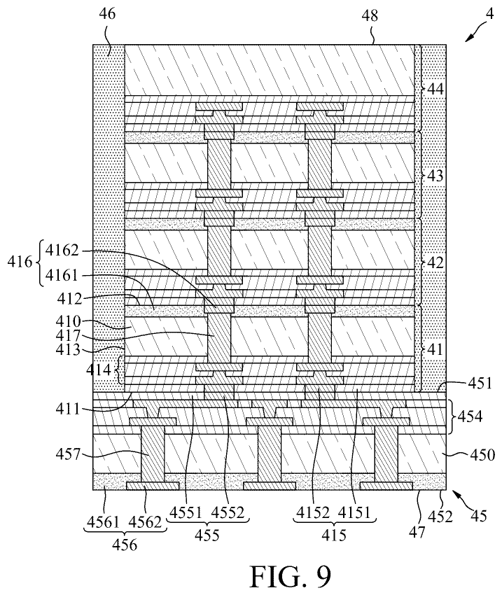

With reference to FIGS. 7A, 7B, 7C, 8 and 9, a logic device 3, a first volatile memory device 4, a first non-volatile memory device 5, a second volatile memory device 4′ and a second non-volatile memory device 5′ may be provided. FIG. 7A may illustrate a top view of FIGS. 7B and 7C. Alternatively, FIG. 7B may illustrate a cross-sectional view of FIG. 7A taken along line IV-IV. FIG. 7C may illustrate a cross-sectional view of FIG. 7A taken along line V-V. FIG. 8 may illustrate a schematic cross-sectional view of the logic device 3 in accordance with some embodiments of the present disclosure. FIG. 9 may illustrate a schematic cross-sectional view of the first volatile memory device 4 in accordance with some embodiments of the present disclosure.

The function and size of the logic device 3 may be different from the function and size of the first volatile memory device 4, the first non-volatile memory device 5, the second volatile memory device 4′ and the second non-volatile memory device 5′.

The function and size of the first volatile memory device 4 may be same as the function and size of the second volatile memory device 4′. The function and size of the first non-volatile memory device 5 may be same as the function and size of the second non-volatile memory device 5′.

In some embodiments, the logic device 3 may be configured to process data or signal, and may be also referred to as “logic die”, “logic chip”, “logic semiconductor die”, or “logic semiconductor chip”. In some embodiments, the logic device 3 may be an application processor (AP) die, a central processing unit (CPU) die, a graphics processing unit (GPU), application specific integrated circuit (ASIC) die, a micro control unit (MCU) die or an input-output (IO) die.

The first volatile memory device 4 and the second volatile memory device 4′ may be configured to store data, and the stored data may be lost when the electrical power is cut off. The first volatile memory device 4 may be also referred to as “first volatile memory die”, “first volatile memory chip”, “first volatile memory semiconductor die”, and “first volatile memory semiconductor chip”. The second volatile memory device 4′ may be also referred to as “second volatile memory die”, “second volatile memory chip”, “second volatile memory semiconductor die”, and “second volatile memory semiconductor chip”.

The first non-volatile memory device 5 and the second non-volatile memory device 5′ may be configured to store data, and the stored data may not be lost (e.g., may be kept) when the electrical power is cut off. The first non-volatile memory device 5 may be also referred to as “first non-volatile memory die”, “first non-volatile memory chip”, “first non-volatile memory semiconductor die”, and “first non-volatile memory semiconductor chip”. The second non-volatile memory device 5′ may be also referred to as “second non-volatile memory die”, “second non-volatile memory chip”, “second non-volatile memory semiconductor die”, and “second non-volatile memory semiconductor chip”.

Referring to FIG. 8, the logic device 3 may have a first surface 31 (e.g., a top surface or a backside surface), a second surface 32 (e.g., a bottom surface or an active surface) and a lateral surface 33. The second surface 32 (e.g., the bottom surface) may be opposite to the first surface 31 (e.g., the top surface). The lateral surface 33 may extend between the first surface 31 (e.g., the top surface) and the second surface 32 (e.g., the bottom surface).

The logic device 3 may include a main portion 30 and a circuit structure 35. A material of the main portion 30 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

The circuit structure 35 may be disposed on the main portion 30. The circuit structure 35 may include a dielectric structure 35a (including a plurality of dielectric layers), at least one circuit layer 35b (including a fourth circuit 351, a fifth circuit 352, a sixth circuit 356, a seventh circuit 353 and an eighth circuit 354), a plurality of inner pads 35c, a plurality of inner vias 35d, a plurality of first bonding pads 36, a plurality of second bonding pads 37 and a plurality of third bonding pads 38. The circuit layer 35b, the inner pads 35c, the inner vias 35d, the first bonding pads 36, the second bonding pads 37 and the third bonding pads 38 are embedded in the dielectric structure 35a. A bottom surface of the first bonding pad 36, a bottom surface of the second bonding pad 37 and a bottom surface of the third bonding pad 38 may be exposed from the second surface 32 of the logic device 3. Each of the first bonding pads 36, the second bonding pads 37 and the third bonding pads 38 may be a hybrid bonding (HB) pad, and may include Cu or Al. Each of the first bonding pads 36, the second bonding pads 37 and the third bonding pads 38 may be a solder bonding pad.

The circuit layer 35b may horizontally connect the inner pads 35c. The inner vias 35d may vertically connect the inner pads 35c and the first bonding pads 36, the second bonding pads 37 and the third bonding pads 38. For example, the first bonding pads 36 may correspond to the fifth circuit 352. The second bonding pads 37 may correspond to the sixth circuit 356. The third bonding pads 38 may correspond to the eighth circuit 354. In some embodiments, the fourth circuit 351, the fifth circuit 352, the sixth circuit 356, the seventh circuit 353 and the eighth circuit 354 of the logic device 3 may not electrically connected to each other in a horizontal direction.

Referring to FIG. 9, the first volatile memory device 4 may be, for example, a high bandwidth memory (HBM). In some embodiments, the first volatile memory device 4 may include a first semiconductor chip 41, a second semiconductor chip 42, a third semiconductor chip 43, a fourth semiconductor chip 44, a base semiconductor chip 45 and an encapsulant 46.

The first semiconductor chip 41 may have a bottom surface 411 (e.g., a first surface), a top surface 412 (e.g., a second surface) and a lateral surface 413 extending between the bottom surface 411 and the top surface 412. The first semiconductor chip 41 may include a first base portion 410, a first conductive structure 414, a first lower structure 415, a first upper structure 416 and a plurality of first conductive vias 417. The first semiconductor chip 41 may be a memory chip such as a dynamic random access memory (DRAM) chip, a static random access memory (SRAM), and/or a resistive random-access memory (RRAM).

The first conductive structure 414 may be disposed on the bottom surface of the first base portion 410. The first conductive vias 417 may extend through the first base portion 410, and may be electrically connected to the first conductive structure 414. In some embodiments, a bottom end of the first conductive vias 417 may extend beyond the bottom surface of the first base portion 410, and may extend into the first conductive structure 414. Thus, the first conductive via 417 may be a monolithic structure, and a length of the first conductive via 417 may be greater than a thickness of the first base portion 410. In some embodiments, the first conductive via 417 may extend beyond the top surface of the first base portion 410.

The first lower structure 415 may be disposed on the first conductive structure 414. The first lower structure 415 may be a hybrid bonding (HB) structure or a solder bonding structure, and may include a first lower dielectric layer 4151 and a plurality of first lower pads 4152. The first lower dielectric layer 4151 may be a hybrid bonding (HB) dielectric layer. Each of the first lower pads 4152 may be a hybrid bonding (HB) pad. Each of the first lower pads 4152 may be a solder bonding pad. The first lower pads 4152 may be embedded in the first lower dielectric layer 4151, and may be exposed by the first lower dielectric layer 4151. The first lower pads 4152 may be surrounded by the first lower dielectric layer 4151. The first lower pads 4152 may be electrically connected to the first conductive vias 417 through the first conductive structure 414.

In some embodiments, a bottom surface of the first lower pad 4152 may be substantially aligned with a bottom surface of the first lower dielectric layer 4151. Thus, the bottom surface of the first lower pad 4152 may be exposed by the bottom surface of the first lower dielectric layer 4151. In some embodiments, a thickness of the first lower pad 4152 may be substantially equal to a thickness of the first lower dielectric layer 4151.

The first upper structure 416 may be disposed on the top surface of the first base portion 410. The first upper structure 416 may be a hybrid bonding (HB) structure, and may include a first upper dielectric layer 4161 and a plurality of first upper pads 4162.

The first upper dielectric layer 4161 may be a hybrid bonding (HB) dielectric layer. Each of the first upper pads 4162 may be a hybrid bonding (HB) pad. The first upper pads 4162 may be embedded in the first upper dielectric layer 4161, and may be exposed by the first upper dielectric layer 4161. The first upper pads 4162 may be surrounded by the first upper dielectric layer 4161. The first upper pads 4162 may be electrically connected to the first conductive vias 417. In some embodiments, the first upper pads 4162 may directly contact the first conductive vias 417. The first upper pads 4162 may be electrically connected to the first lower pad 4152 through the first conductive vias 417 and the first conductive structure 414.

In some embodiments, a top surface of the first upper pad 4162 may be substantially aligned with a top surface of the first upper dielectric layer 4161. Thus, the top surface of the first upper pad 4162 may be exposed by the top surface of the first upper dielectric layer 4161. The bottom surface of the first upper pad 4162 may contact the first conductive via 417. In some embodiments, a thickness of the first upper pad 4162 may be less than a thickness of the first upper dielectric layer 4161.

The second semiconductor chip 42 may be stacked on the first semiconductor chip 41, and may be electrically connected to the first semiconductor chip 41 by hybrid bonding or metal-to-metal bonding. The structure of the second semiconductor chip 42 may be same as or similar to the structure of the first semiconductor chip 41.

The third semiconductor chip 43 may be stacked on the second semiconductor chip 42, and may be electrically connected to the second semiconductor chip 42 by hybrid bonding or metal-to-metal bonding. The structure of the third semiconductor chip 43 may be same as or similar to the structure of the first semiconductor chip 41.

The fourth semiconductor chip 44 may be stacked on the third semiconductor chip 43, and may be electrically connected to the third semiconductor chip 43 by hybrid bonding or metal-to-metal bonding. The structure of the fourth semiconductor chip 44 may be similar to the structure of the first semiconductor chip 41, except that the fourth semiconductor chip 44 may not include the first upper structure 416 and the first conductive vias 417 of the first semiconductor chip 41.

The base semiconductor chip 45 (or a fifth semiconductor chip) may have a top surface 451 (e.g., a first surface) and a bottom surface 452 (e.g., a second surface). The base semiconductor chip 45 may include a fifth base portion 450, a fifth conductive structure 454, a fifth upper structure 455, a plurality of fifth conductive vias 457 and a fifth lower structure 456. The base semiconductor chip 45 may be a controller chip such as an application processor (AP) chip.

The fifth conductive structure 454 may be disposed on the top surface of the fifth base portion 450. The fifth conductive vias 457 may extend through the fifth base portion 450, and may be electrically connected to the fifth conductive structure 454. In some embodiments, an end of the fifth conductive via 457 may extend into the fifth conductive structure 454.

The fifth upper structure 455 may be disposed on the fifth conductive structure 454. The fifth upper structure 455 may be a hybrid bonding (HB) structure or a solder bonding structure, and may include a fifth upper dielectric layer 4551 and a plurality of fifth upper pads 4552. The fifth upper dielectric layer 4551 may be a hybrid bonding (HB) dielectric layer. Each of the fifth upper pads 4552 may be a hybrid bonding (HB) pad. The fifth upper pads 4552 may be embedded in the fifth upper dielectric layer 4551, and may be exposed by the fifth upper dielectric layer 4551.

The fifth lower structure 456 may be disposed on the bottom surface of the fifth base portion 450. The fifth lower structure 456 may be a hybrid bonding (HB) structure or a solder bonding structure, and may include a fifth lower dielectric layer 4561 and a plurality of fifth lower pads 4562. The fifth lower dielectric layer 4561 may be a hybrid bonding (HB) dielectric layer. Each of the fifth lower pads 4562 may be a hybrid bonding (HB) pad. The fifth lower pads 4562 may be embedded in the fifth lower dielectric layer 4561, and may be exposed by the fifth lower dielectric layer 4561.

The first lower pads 4152 of the first lower structure 415 of the first semiconductor chip 41 may be bonded to and electrically connected to the fifth upper pad 4552 of the fifth upper structure 455 of the base semiconductor chip 45 through hybrid bonding.

The encapsulant 46 may be a molding compound with or without fillers. The encapsulant 46 may encapsulate the first semiconductor chip 41, the second semiconductor chip 42, the third semiconductor chip 43, the fourth semiconductor chip 44 and the top surface 451 of the base semiconductor chip 45. The encapsulant 46 may cover the lateral surface 413 of the first semiconductor chip 41, the lateral surface of the second semiconductor chip 42, the lateral surface of the third semiconductor chip 43, the lateral surface of the fourth semiconductor chip 44 and the top surface 451 of the base semiconductor chip 45.

Referring to FIG. 7C, the first non-volatile memory device 5 may be a read-only memory (ROM), a flash memory, and/or a non-volatile random access memory (NVRAM). In some embodiments, the first non-volatile memory device 5 may include a first die 51 and a second die 52 stacked on the first die 51.

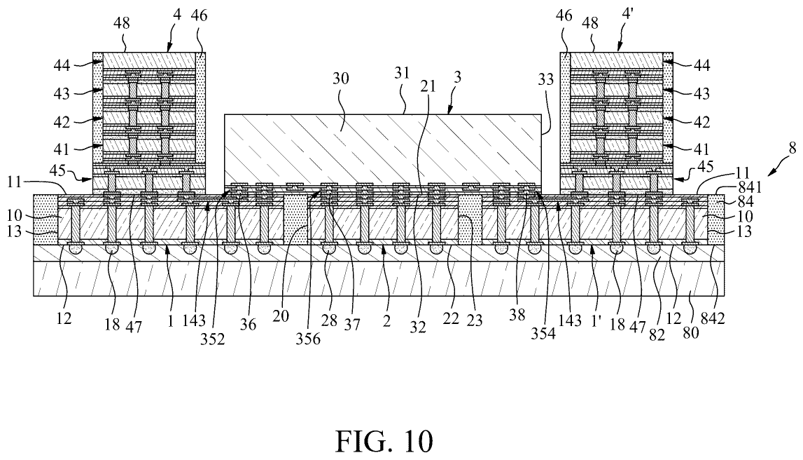

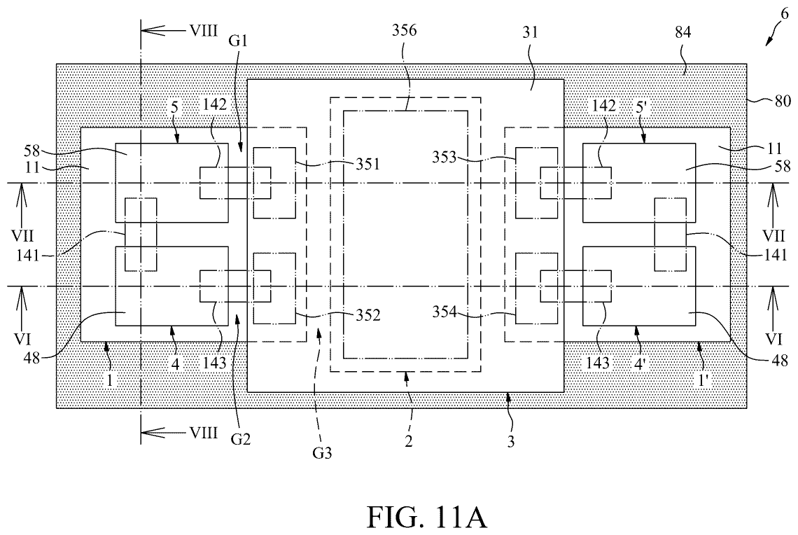

With reference to FIG. 10, at step S901, the logic device 3 may be electrically connected to and bonded to the first memory controller device 1, the second memory controller device 1′ and the interconnection device 2. In addition, at step S902, the first volatile memory device 4 and the first non-volatile memory device 5 may be electrically connected to and bonded to the first memory controller device 1. Further, the second volatile memory device 4′ and the second non-volatile memory device 5′ may be electrically connected to and bonded to the second memory controller device 1′.

With reference to FIGS. 11A, 11B, 11C, and 11D, the carrier 80 and the adhesive layer 82 may be removed from the molded structure 8 so as to form a package structure 6. FIG. 11A may illustrate a top view of FIGS. 11B, 11C and 11D. Alternatively, FIG. 11B may illustrate a cross-sectional view of FIG. 11A taken along line VI-VI. FIG. 11C may illustrate a cross-sectional view of FIG. 11A taken along line VII-VII. FIG. 11D may illustrate a cross-sectional view of FIG. 11A taken along line VIII-VIII.

The logic device 3 may be disposed over and electrically connected to the interconnection device 2, the first memory controller device 1 and the second memory controller device 1′. The first non-volatile memory device 5 may be disposed over and electrically connected to the first memory controller device 1. The first volatile memory device 4 may be disposed side by side with the first non-volatile memory device 5, and may be disposed over and electrically connected to the first memory controller device 1. The second non-volatile memory device 5′ may be disposed over and electrically connected to the second memory controller device 1′. The second volatile memory device 4′ disposed side by side with the second non-volatile memory device 5′, and may be disposed over and electrically connected to the second memory controller device 1′.

The interconnection device 2 may be entirely disposed within a projection of the logic device 3 in a vertical direction. The vertical direction may be defined as a direction substantially perpendicular to the top surface 21 of the interconnection device 2 or the top surface 11 of the first memory controller device 1. The sixth circuit 356 of the logic device 3 may be entirely disposed within a projection of the interconnection device 2 in the vertical direction. The sixth circuit 356 of the logic device 3 may be electrically connected to the conductive structure 24 of the interconnection device 2 by hybrid bonding. Thus, the second bonding pads 37 corresponding to the sixth circuit 356 of the logic device 3 may be bonded to or attached to the upper pads 252 (FIG. 4) of the upper structure 25 of the interconnection device 2 by metal-to-metal bonding. The dielectric structure 35a of the circuit structure 35 of the logic device 3 may be directly attached to or may directly contact the upper dielectric layer 251 (FIG. 4) of the upper structure 25 of the interconnection device 2.

Referring to FIG. 11B, in some embodiments, the fifth circuit 352 of the logic device 3 may overlap and electrically connect the third circuit 143 of the first memory controller device 1 in the vertical direction. The logic device 3 may be electrically connected to the first memory controller device 1 by hybrid bonding. Thus, the first bonding pads 36 corresponding to the fifth circuit 352 of the logic device 3 may be bonded to or attached to the first upper pads 152 (FIG. 3) of the first upper structure 15 of the first memory controller device 1 corresponding to the third circuit 143 by metal-to-metal bonding. The dielectric structure 35a of the circuit structure 35 of the logic device 3 may be directly attached to or may directly contact the first upper dielectric layer 151 of the first upper structure 15 of the first memory controller device 1.

Similarly, the eighth circuit 354 of the logic device 3 may overlap and electrically connect the third circuit 143 of the second memory controller device 1′ in the vertical direction. The logic device 3 may be electrically connected to the second memory controller device 1′ by hybrid bonding. Thus, the third bonding pads 38 corresponding to the eighth circuit 354 of the logic device 3 may be bonded to or attached to upper pads of the second memory controller device 1′ corresponding to the third circuit 143 of the second memory controller device 1′ by metal-to-metal bonding. The dielectric structure 35a of the circuit structure 35 of the logic device 3 may be directly attached to or may directly contact an upper layer of an upper structure of the second memory controller device 1′.

Referring to FIG. 11A, in some embodiments, the fourth circuit 351 of the logic device 3 may overlap and electrically connect the second circuit 142 of the first memory controller device 1 in the vertical direction. Similarly, the seventh circuit 353 of the logic device 3 may overlap and electrically connect the second circuit 142 of the second memory controller device 1′ in the vertical direction. The logic device 3 may overlap the first memory controller device 1 and the second memory controller device 1′ in the vertical direction.

The logic device 3, the first non-volatile memory device 5, the first volatile memory device 4, the second non-volatile memory device 5′, the second volatile memory device 4′ are disposed side by side. The first non-volatile memory device 5 may be disposed over the molded structure 8, and may be electrically connected to the fourth circuit 351 of the logic device 3 through the second circuit 142 of the first memory controller device 1. The first volatile memory device 4 may be disposed over the molded structure 8, and may be electrically connected to the fifth circuit 352 of the logic device 3 through the third circuit 143 of the first memory controller device 1. As shown in FIG. 11D, the first volatile memory device 4 may be electrically connected to the first non-volatile memory device 5 through the first circuit 141 of the first memory controller device 1.

Referring to FIG. 11A, the first non-volatile memory device 5 and the first volatile memory device 4 may be entirely disposed within a projection of the first memory controller device 1 in the vertical direction. As shown in FIG. 11D, both of the first non-volatile memory device 5 and the first volatile memory device 4 may overlap the first circuit 141 of the first memory controller device 1 in the vertical direction. Both of the first non-volatile memory device 5 and the first volatile memory device 4 are electrically connected to the first memory controller device 1 by hybrid bonding. For example, the fifth lower pads 4562 of the first volatile memory device 4 may be bonded to or attached to the first upper pads 152 (FIG. 3) of the first upper structure 15 of the first memory controller device 1 by metal-to-metal bonding. The fifth lower dielectric layer 4561 of the first volatile memory device 4 may be directly attached to or may directly contact the first upper dielectric layer 151 of the first upper structure 15 of the first memory controller device 1.

The second non-volatile memory device 5′ and the second volatile memory device 4′ may be entirely disposed within a projection of the second memory controller device 1′ in the vertical direction. Both of the second non-volatile memory device 5′ and the second volatile memory device 4′ may overlap the first circuit 141 of the second memory controller device 1′ in the vertical direction. Both of the second non-volatile memory device 5′ and the second volatile memory device 4′ are electrically connected to the second memory controller device 1′ by hybrid bonding.

Referring to FIGS. 11A and 11B, a gap G1 between the logic device 3 and the first non-volatile memory device 5 may overlap the second circuit 142 of the first memory controller device 1 in the vertical direction. A gap G2 between the logic device 3 and the first volatile memory device 4 may overlap the third circuit 143 of the first memory controller device 1 in the vertical direction. A gap G3 between the first memory controller device 1 and the interconnection device 2 may overlap the logic device 1 in the vertical direction.

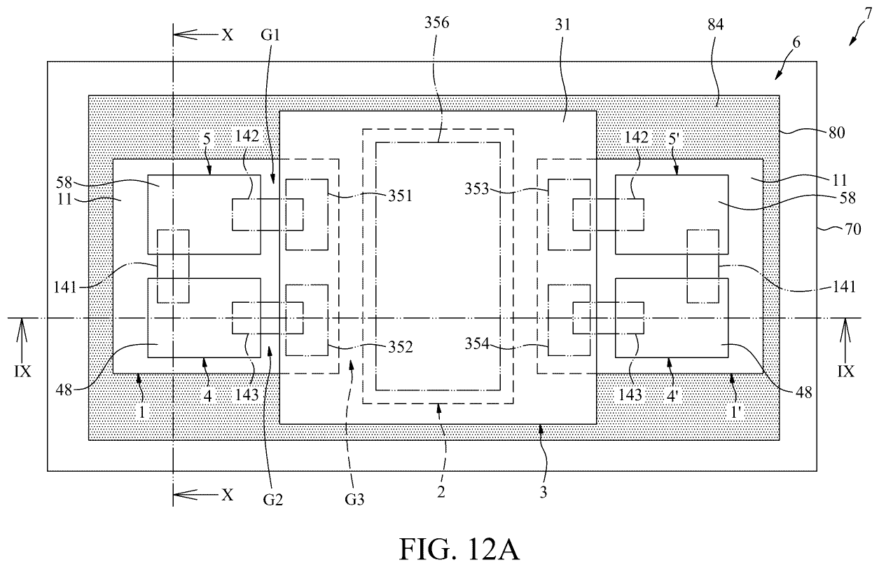

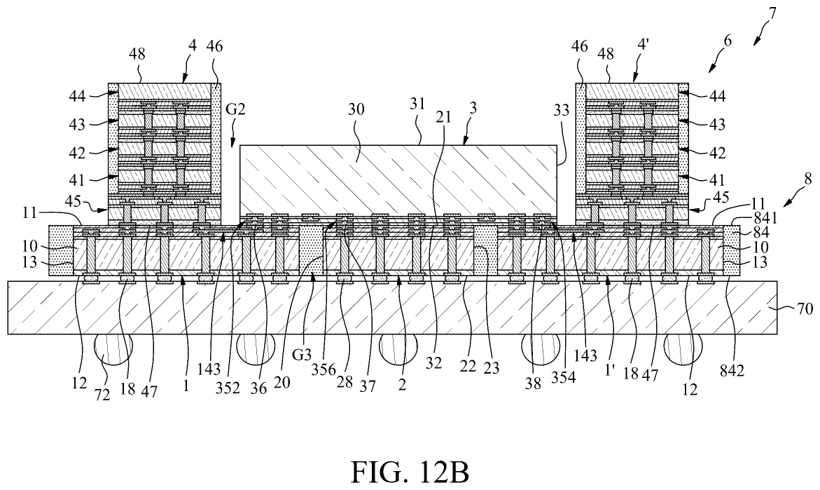

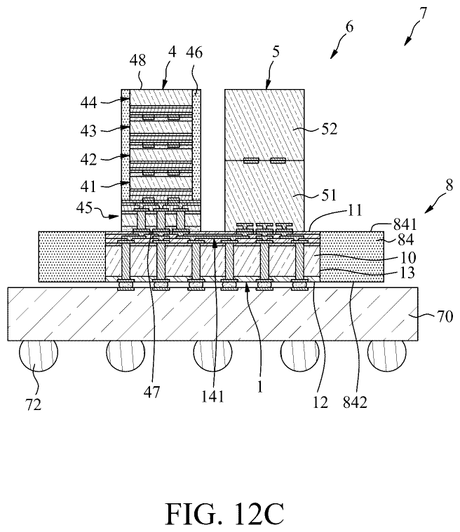

With reference to FIGS. 12A, 12B and 12C, the package structure 6 may be attached to and electrically connected to a substrate 70 through the solder materials 18, 28 so as to form an assembly structure 7. FIG. 12A may illustrate a top view of FIGS. 12B and 12C. Alternatively, FIG. 12B may illustrate a cross-sectional view of FIG. 12A taken along line IX-IX. FIG. 12C may illustrate a cross-sectional view of FIG. 12A taken along line X-X.

The substrate 70 may be a semiconductor substrate, and may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. In some embodiments, the substrate 70 may include a semiconductor-on-insulator substrate, such as a silicon-on-insulator (SOI) substrate, a silicon germanium-on-insulator (SGOI) substrate, or a germanium-on-insulator (GOI) substrate. In some embodiments, the substrate 70 may include organic material, glass, ceramic material or the like. For example, the substrate 70 may be made of a cured photoimageable dielectric (PID) material such as epoxy or polyimide (PI) including photoinitiators. For example, the substrate 70 may include a homogeneous material. For example, the material of the substrate 70 may include epoxy type FR5, FR4, Bismaleimide triazine (BT), print circuit board (PCB) material, Prepreg (PP), Ajinomoto build-up film (ABF) or other suitable materials.

In the assembly structure 7, the molded structure 8 may be disposed over and electrically connected to the substrate 70. Thus, the interconnection device 2 may be disposed over and electrically connected to the substrate 70. The first memory controller device 1 may be disposed over and electrically connected to the substrate 1. The second memory controller device 1′ may be disposed over and electrically connected to the substrate 70.

Then, a plurality of external connectors 72 may be disposed on the bottom surface of the substrate 70 to provide electrical connections, for example, I/O connections, of the substrate 70. Each of the external connector 72 may include a reflowable material such as a solder ball or solder material including AgSn.

FIGS. 12A, 12B and 12C illustrate an assembly structure 7 in accordance with some embodiments of the present disclosure. FIG. 12A is a top view of FIGS. 12B and 12C. FIG. 12B is a cross-sectional view of FIG. 12A taken along line IX-IX. FIG. 12C is a cross-sectional view of FIG. 12A taken along line X-X.

The assembly structure 7 may include the substrate 70 and the package structure 6 disposed over and electrically connected to the substrate 70. The package structure 6 may include the molded structure 8, the logic device 3, the first non-volatile memory device 5, the first volatile memory device 4, the second non-volatile memory device 5′ and the second volatile memory device 4′. The molded structure 8 may include the first memory controller device 1, the interconnection device 2, the second memory controller device 1′ and the encapsulant 84 encapsulating the first memory controller device 1, the interconnection device 2, the second memory controller device 1′.

The logic device 3 may be electrically connected to and bonded to the first memory controller device 1, the second memory controller device 1′ and the interconnection device 2.

The first non-volatile memory device 5 and the first volatile memory device 4 may be entirely disposed within a projection of the first memory controller device 1 in the vertical direction. Both of the first non-volatile memory device 5 and the first volatile memory device 4 are electrically connected to the first memory controller device 1.

The second non-volatile memory device 5′ and the second volatile memory device 4′ may be entirely disposed within a projection of the second memory controller device 1′ in the vertical direction. Both of the second non-volatile memory device 5′ and the second volatile memory device 4′ are electrically connected to the second memory controller device 1′.

In the embodiment illustrated in FIGS. 12A, 12B and 12C, the heterogeneous electronic devices (such as semiconductor chips or semiconductor dice) may be integrated in the assembly structure 7 and the package structure 6 without redistribution structure or interposer. For example, the first non-volatile memory device 5 and the first volatile memory device 4 may be communicated with each other through the first circuit 141 of the first memory controller device 1. The first non-volatile memory device 5 and the logic device 3 may be communicated with each other through the second circuit 142 of the first memory controller device 1. The first volatile memory device 4 and the logic device 3 may be communicated with each other through the third circuit 143 of the first memory controller device 1.

In addition, the logic device 3 may be directly communicated with the substrate 70 through the interconnection device 2. The first volatile memory device 4 and the first non-volatile memory device 5 may be directly communicated with the substrate 70 through the first memory controller device 1. The second volatile memory device 4′ and the second non-volatile memory device 5′ may be directly communicated with the substrate 70 through the second memory controller device 1′.

Therefore, the assembly structure 7 and the package structure 6 may satisfy multiple required functions. Thus, the design flexibility is increased, and the manufacturing cost is reduced.

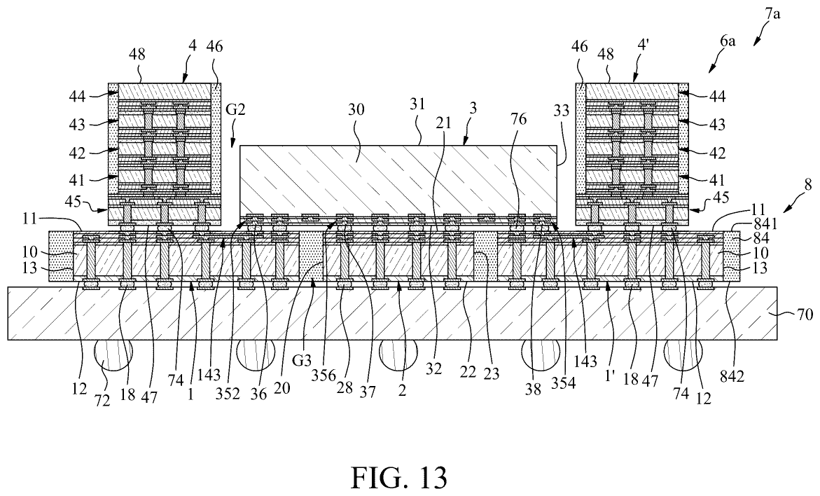

FIG. 13 is a schematic cross-sectional view of an assembly structure 7a in accordance with some embodiments of the present disclosure. The assembly structure 7a may be similar to the assembly structure 7 of FIG. 12B except for the structure of the package structure 6a. In the package structure 6a, the logic device 3 is electrically connected to the interconnection device 2, the first memory controller device 1 and the second memory controller device 1′ through a plurality of solder materials 76. Both of the first non-volatile memory device 5 and the first volatile memory device 4 are electrically connected to the first memory controller device 1 through a plurality of solder materials 74. Both of the second non-volatile memory device 5′ and the second volatile memory device 4′ are electrically connected to the second memory controller device 1′ through a plurality of solder materials 74. The solder materials 74, 76 may include a reflowable material such as AgSn.

One aspect of the present disclosure provides a package structure including a molded structure, a logic device, a non-volatile memory device and a volatile memory device. The molded structure includes a memory controller device, an interconnection device and an encapsulant. The memory controller device includes a conductive structure including a first circuit, a second circuit and a third circuit. The interconnection device is disposed side by side with the memory controller device, and includes a conductive structure. The encapsulant encapsulates the memory controller device and the interconnection device. The logic device is disposed over the molded structure, and includes a conductive structure including a fourth circuit, a fifth circuit and a sixth circuit. The sixth circuit of the logic device is electrically connected to the conductive structure of the interconnection device. The non-volatile memory device is disposed over the molded structure, and electrically connected to the fourth circuit of the logic device through the second circuit of the memory controller device. The volatile memory device is disposed over the molded structure, and electrically connected to the fifth circuit of the logic device through the third circuit of the memory controller device. The volatile memory device is electrically connected to the non-volatile memory device through the first circuit of the memory controller device.

Another aspect of the present disclosure provides an assembly structure including a substrate, an interconnection device, a first memory controller device, a second memory controller device, a logic device, a first non-volatile memory device, a first volatile memory device, a second non-volatile memory device and a second volatile memory device. The interconnection device is disposed over and electrically connected to the substrate. The first memory controller device is disposed over and electrically connected to the substrate. The second memory controller device is disposed over and electrically connected to the substrate, wherein the first memory controller device and the second memory controller device are disposed at different sides of the interconnection device. The logic device is disposed over and electrically connected to the interconnection device, the first memory controller device and the second memory controller device. The first non-volatile memory device is disposed over and electrically connected to the first memory controller device. The first volatile memory device is disposed side by side with the first non-volatile memory device, and disposed over and electrically connected to the first memory controller device. The second non-volatile memory device is disposed over and electrically connected to the second memory controller device. The second volatile memory device is disposed side by side with the second non-volatile memory device, and disposed over and electrically connected to the second memory controller device.

Another aspect of the present disclosure provides a manufacturing method. The manufacturing method includes: providing a molded structure, wherein the molded structure includes a first memory controller device, an interconnection device disposed side by side with the first memory controller device, and an encapsulant encapsulating the first memory controller device and the interconnection device; electrically connecting a logic device to the first memory controller device and the interconnection device; and electrically connecting a first volatile memory device and a first non-volatile memory device to the first memory controller device.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A package structure, comprising:
a molded structure comprising:
a memory controller device including a conductive structure including a first circuit, a second circuit and a third circuit;
an interconnection device disposed side by side with the memory controller device, and including a conductive structure; and
an encapsulant encapsulating the memory controller device and the interconnection device;
a logic device disposed over the molded structure, and including a circuit structure including a fourth circuit, a fifth circuit and a sixth circuit, wherein the sixth circuit of the logic device is electrically connected to the conductive structure of the interconnection device;
a non-volatile memory device disposed over the molded structure, and electrically connected to the fourth circuit of the logic device through the second circuit of the memory controller device; and
a volatile memory device disposed over the molded structure, and electrically connected to the fifth circuit of the logic device through the third circuit of the memory controller device, wherein the volatile memory device is electrically connected to the non-volatile memory device through the first circuit of the memory controller device.

2. The package structure of claim 1, wherein a top surface and a bottom surface of the memory controller device are substantially aligned with a top surface and a bottom surface of the encapsulant, respectively.

3. The package structure of claim 1, wherein a top surface and a bottom surface of the interconnection device are substantially aligned with a top surface and a bottom surface of the encapsulant, respectively.

4. The package structure of claim 1, wherein the interconnection device is entirely disposed within a projection of the logic device in a vertical direction.

5. The package structure of claim 4, wherein the sixth circuit of the logic device is entirely disposed within a projection of the interconnection device in the vertical direction.

6. The package structure of claim 1, wherein the fourth circuit of the logic device overlaps the second circuit of the memory controller device in a vertical direction.

7. The package structure of claim 1, wherein the fifth circuit of the logic device overlaps the third circuit of the memory controller device in a vertical direction.

8. The package structure of claim 1, wherein the logic device, the non-volatile memory device and the volatile memory device are disposed side by side.

9. The package structure of claim 1, wherein the non-volatile memory device and the volatile memory device are entirely disposed within a projection of the memory controller device in a vertical direction.

10. The package structure of claim 1, wherein both of the non-volatile memory device and the volatile memory device overlap the first circuit of the memory controller device in a vertical direction.

11. The package structure of claim 1, wherein the logic device is electrically connected to the interconnection device by hybrid bonding, and the logic device is electrically connected to the memory controller device by hybrid bonding.

12. The package structure of claim 1, wherein both of the non-volatile memory device and the volatile memory device are electrically connected to the memory controller device by hybrid bonding.

13. The package structure of claim 1, wherein the logic device is electrically connected to the interconnection device through a plurality of solder materials, and the logic device is electrically connected to the memory controller device through a plurality of solder materials.

14. The package structure of claim 1, wherein both of the non-volatile memory device and the volatile memory device are electrically connected to the memory controller device through a plurality of solder materials.

15. The package structure of claim 1, wherein a gap between the logic device and the non-volatile memory device overlaps the second circuit of the memory controller device in a vertical direction.

16. The package structure of claim 1, wherein a gap between the logic device and the volatile memory device overlaps the third circuit of the memory controller device in a vertical direction.

17. The package structure of claim 1, wherein a gap between the memory controller device and the interconnection device overlaps the logic device in a vertical direction.

18. The package structure of claim 1, wherein the first circuit, the second circuit and the third circuit of the memory controller device do not electrically connected to each other in a horizontal direction.

19. The package structure of claim 1, wherein the fourth circuit, the fifth circuit and the sixth circuit of the logic device do not electrically connected to each other in a horizontal direction.

20. The package structure of claim 1, wherein the memory controller device includes a memory controller semiconductor die or a memory controller semiconductor chip, the interconnection device includes an interconnection semiconductor die or an interconnection semiconductor chip, and the encapsulant includes a molding compound.
